(19) United States
(12) Patent Application Publication
(10) Pub. No.: US 2011/0162693 A1
(43) Pub. Date: Jul. 7, 2011

(54) Connection System for a Solar Electric Power Conversion System

(75) Inventors: Christopher G.E. Nightingale, Singapore (SG); Boon Hou Tay, Singapore (SG); Swee Ming Goh, Singapore (SG)

(73) Assignees: ALTERNATIVE ENERGY TECHNOLOGY PTE. LTD., Singapore (SG); DRAGON ENERGY PTE. LTD., Singapore (SG)

(21) Appl. No.: 12/904,118

(22) Filed: Oct. 13, 2010

(30) Foreign Application Priority Data
Oct. 13, 2009 (SG) 200906840-4

(51) Int. Cl. H01L 31/048

(52) U.S. Cl. 136/251

(57) ABSTRACT

A connection system 10 comprises: a base 24 configured to support the photovoltaic panels 22a and 22b in a manner where they face the different directions D1 and D2 respectively; and, an electric circuit 26 which is supported by the base 24 and electrically couples the panels 22a and 22b together as well as enabling the electrical connection of the connection system 10 to a second like connection system. The base 24 is coupled to each of the PV panels 22 at two spaced apart locations by posts 30a1, 30a2, 30b1, 30b2 and a ridge plate 32 which provides support for each of the panels 22 along the length of an upper edge of each PV panel 22. The electric circuit 26 comprises: a sub-circuit 54 which is housed in the cavity 40; electrical terminals 56 that demountably engage the posts 30; and electrical connectors 58a and 58b which provide electrical connection with adjacent connection systems 10.

### CROSS-REFERENCE TO RELATED PATENT APPLICATION

This application claims the benefit of Singapore Patent Application No. 200906840-4, filed on Oct. 13, 2009, the disclosure of which is incorporated herein in its entirety by reference.

### BACKGROUND OF THE INVENTION

1. Field of the Invention

The present invention relates to the generation of solar electric power particularly, although not exclusively, for domestic or residential use.

2. Background

Photovoltaic panels are readily available for mounting on roofs for the purposes of generating solar electric power. The panels are often carried by a base or support structure that mimics the shape and configuration of conventional roof coverings such as tiles or shingles. This enables the photovoltaic panels to be easily mounted on convention roof structures. However, such support structures are not normally suitable for enabling the efficient harvesting of solar energy from the ridge of a roof or top of a perimeter wall or fence.

### SUMMARY OF THE INVENTION

According to one aspect of the invention there is provided a connection system for a solar electric power conversion system having a plurality of photovoltaic panels, the connection system comprising:
a base configured to support the photovoltaic panels in a manner where at least a first panel and a second panel face different respective first and second directions; and,
an electric circuit supported by the base for electrically coupling the photovoltaic panels together and enabling electrical connection of the connection system to a second like connection system.

The base may be coupled to each of the panels at least two spaced apart locations.

The base may support each panel along a length of an edge thereof.

The base may comprise at least two posts for supporting the photovoltaic panels.

At least one of the posts may extend in the first direction and at least one of the posts extends in the second direction.

At least two of the posts may extend in the first direction and support the first photovoltaic panel, and at least two of the posts may extend in the second direction and support the second photovoltaic panel.

The base may comprise a first surface from which the posts extend.

The base may comprise a cavity on a side of the first surface opposite the posts.

The posts may be integrally formed with the base, for example by a moulding or casting process. This process may use plastics or otherwise non-electrically conducting materials so that the posts are not electrically conducting.

The connection system may comprise a cover detachably coupled to the base to cover the cavity.

The electrical connection system comprises a sub-circuit housed in the cavity.

The electric circuit may comprise electric terminals coupled to the posts, the electric terminals providing electrical connection between the photovoltaic panels and the sub-circuit.

The sub-circuit may be configured to electrically connect the photovoltaic panels in series.

The sub-circuit may comprise for each photovoltaic panel, a bypass diode electrically connected between the electric terminals coupled to corresponding photovoltaic panel.

The electric circuit may comprise first and second electrical connectors configured to enable electrical coupling of the connection system with a second like connection system.

The electrical connectors may be coupled with the sub-circuit in a manner whereby the photovoltaic panels coupled to the connection system are electrically coupled in series with photovoltaic panels coupled to a second like connection system.

The electric terminals may be demountably coupled to the posts to facilitate replacement of the electric terminals with terminals of different configuration.

Each electric terminal may comprise a shaft, and a face at an end of the shaft, the face provided with a recess for receiving a fastener for fastening a photovoltaic panel to the electric terminal.

The electric terminals may be provided with shafts having a selection of different lengths and faces lying in planes at a selection of different angles to a longitudinal axis of the shaft.

The connection system may further comprise a ridge plate that comprises surfaces facing in both the first and second directions, the ridge plate connected to the base and underlying the photovoltaic panels.

A second aspect of the invention may provide a solar electric capping unit comprising:
first and second photovoltaic panels; and,
a connection system configured to support the panels in a manner wherein the first panel faces a first direction and a second panel faces a second direction different to the first direction, the connection system further arranged to electrically couple the photovoltaic panels together and to enable electrical connection with a second light solar capping unit.

In the solar electric capping unit the connection system comprises the connection system in accordance with the first aspect of the invention.

### BRIEF DESCRIPTION OF THE DRAWINGS

An embodiment of the present invention will be described by way of example only with reference to the accompanying Figures in which:

FIG. 1a is a schematic representation of a plurality of connection systems in accordance with an embodiment of the invention fitted along a ridge of a roof;

FIG. 1b is an end view of the roof shown in FIG. 1a;

FIG. 2 is an exploded view of the connection system with photovoltaic panels;

FIG. 3 is a bottom perspective view of a base of the connection system with a cove of the base open;

FIG. 4 depicts a configuration of edges of the photovoltaic panels coupled to the connection system;

FIG. 5 is a section view of the connection system with attached photovoltaic panels;

FIG. 6 is a section view of an electric terminal incorporated in the connection system;

FIG. 7 is a representation of a sub-circuit incorporated in the connection system;

FIG. 8 is a circuit diagram of three connection systems electrically coupled together;

FIGS. 9a-9h depict one possible sequence of steps for installing a plurality of connection systems and fitting corresponding photovoltaic panels along a ridge of a roof;

FIG. 10a is a schematic representation of one form of waterproofing components that may be incorporated in the connection system;

FIG. 10b is an end view of a second form of a waterproofing component that can be incorporated in the connection system;

FIG. 10c is a bottom view of the second waterproofing component shown in FIG. 10b;

FIGS. 11a and 11b depict section views of one configuration of roof and corresponding electric terminal respectively in relation to which the connection system may be used;

FIGS. 12a and 12b depict section views of another configuration of roof and corresponding electric terminal respectively in relation to which the connection system may be used; and,

FIGS. 13a and 13b depict section views of a further configuration of roof and corresponding electric terminal respectively in relation to which the connection system may be used.

### DETAILED DESCRIPTION OF SPECIFIC EMBODIMENTS

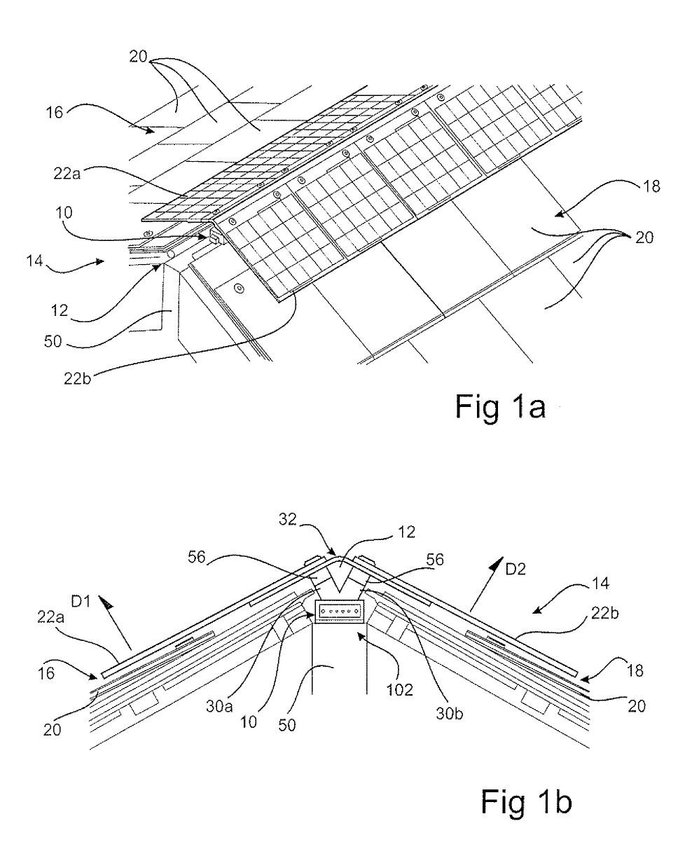

FIGS. 1a and 1b illustrate an embodiment of the connection system 10 applied along a ridge 12 of a pitched roof 14. The roof 14 has surfaces 16 and 18 facing in different directions. Surfaces 16 and 18 are also covered with a plurality of photovoltaic panels 20. The panels 20 which are coupled to the surfaces 16 and 18 are provided for illustrated purposes only and do not form part of the present embodiment. The connection system 10 supports respective photovoltaic panels 22a and 22b (hereinafter referred to in general as “PV panels 22”). The panels 22a and 22b face different directions. Specifically, the panel 22a faces a first direction D1 that extends perpendicular to the plane of the surface 16. The panel 22b faces direction D2 which is perpendicular to the plane of the surface 18. As is apparent from FIGS. 1a and 1b, the connection system 10 enables the harvesting of solar energy from along the ridge 12 of the roof 14.

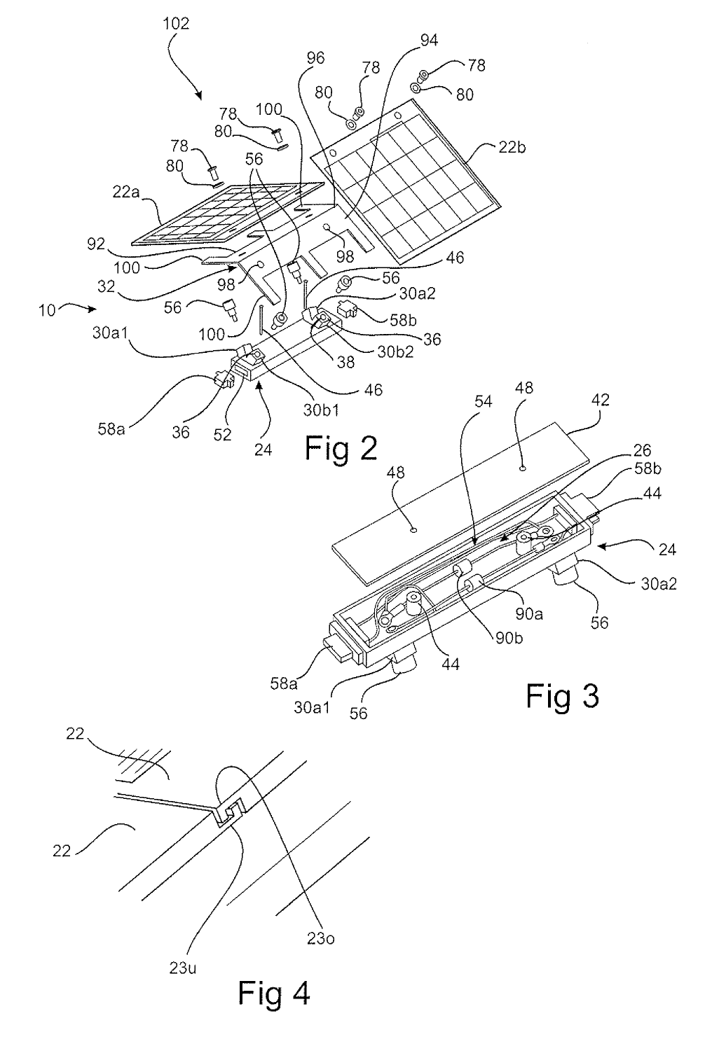

Referring to FIGS. 2 and 3, an embodiment of the connection system 10 comprises; a base 24 configured to support the photovoltaic panels 22a and 22b in a manner where they face the different directions D1 and D2 respectively; and, an electric circuit 26 which is supported by the base 24 and electrically couples the panels 22a and 22b together as well as enabling the electrical connection of the connection system 10 to a second like connection system (shown in FIGS. 1a, 8, 9c and 9d). The PV panels 22 may be provided with interlocking overlapping and underlapping edges 23o and 23u as shown in FIG. 4 in order to provide waterproofing between the adjacent PV panels 22 of adjacent connection systems 10.

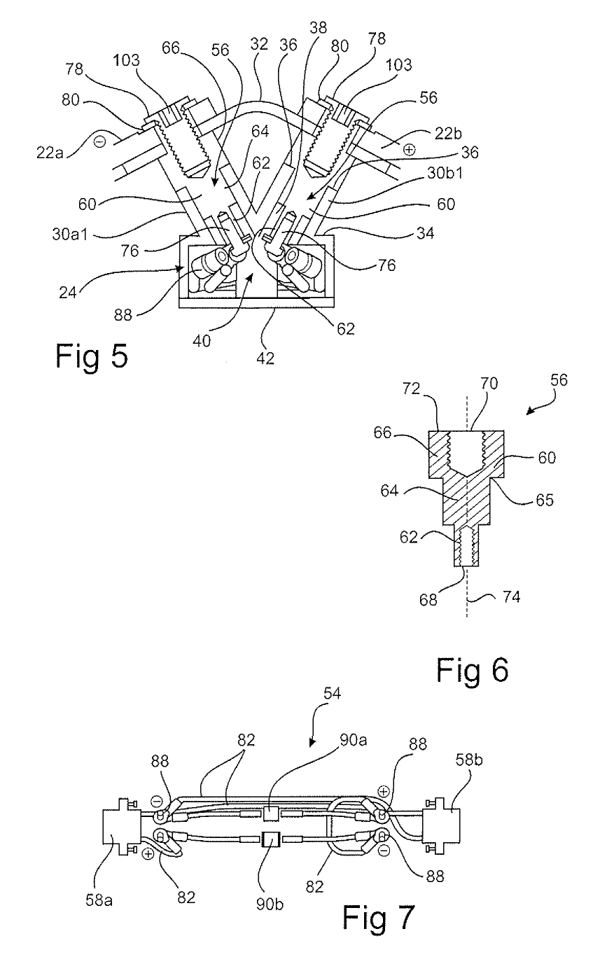

The base 24 is coupled to each of the PV panels 22 at two spaced apart locations but provides support for each of the panels 22 along the length of an upper edge of each PV panel 22. This is facilitated by the provision of posts 30a1, 30a2, 30b1, 30b2 (hereinafter referred to in general as “posts 30”) and a ridge plate 32 as explained in greater detail below. The posts 30 extend from a first surface 34 of the base 24. More particularly, the posts 30 extend at an acute angle from the surface 34. The posts 30a1 and 30a2 extend in the direction D1, while the posts 30b1 and 30b2 extend in a direction D2. Thus the posts 30a1 and 30a2 diverge from the posts 30b1 and 30b2. As shown most clearly in FIG. 5, the posts 30 are formed integrally with the base 24. In one embodiment, this may be arranged by forming the base 24 by a moulding process using a plastics material. Each post 30 is formed with an end surface 36 which lies in a plane perpendicular to the direction D1 or D2 (as the case may be) in which the post 30 extends. A hole 38 extends into each post 30 opening onto the end surface 36.

The base 24 is in a general configuration and shape of a rectangular box with an open bottom and defines a cavity 40 on a side of the surface 34 opposite the posts 30. The open bottom and thus the cavity 40 are covered by a cover plate 42. The cavity may be sealed by a sealant or gasket between the cover 42 and bottom of the box. Two bosses 44 extend from the inside of the first surface 34 and extend to the cover plate 42. Each of the bosses 44 is provided with a through hole for receipt of a mechanical fastener 46 such as a nail or screw. The cover plate 42 is also provided with a pair of holes 48 that register with the through holes in the bosses 44. When the connection system 10 is used to support photovoltaic panels along the ridge 12 of a roof 14, the base 24 is orientated so that the surface 34 is uppermost, and the base plate 42 lies on an underlying ridge beam 50. The connection system 10 is attached to the roof 14 by the fasteners 46 which pass through the holes in the bosses 44 and the holes 48 in the cover plate and extend into the ridge beam 50. The base 24 is also provided at its opposite ends with openings 52 which allows for electrical connection between the electric circuits 26 of adjacent coupling systems 10 as will be explained in greater detail below.

The electric circuit 26 comprises: a sub-circuit 54 which is housed in the cavity 40; electrical terminals 56 that demountably engage the posts 30; and electrical connectors 58a and 58b (hereinafter referred to in general as “connectors 58”) that fit in the openings 52 to provide electrical connection with an adjacent coupling system 10.

With particular reference to FIGS. 5 and 6, the terminals 56 comprise a shaft 60 having an inner most portion 62, a contiguous intermediate portion 64, and a contiguous distal portion 66. Each of the portions 62, 64 and 66 is of a cylindrical shape but the outer diameter of the portions increases in a stepwise fashion from the inner portion to the distal portions 66. Thus the inner portion 62 has the smallest diameter while the outer distal portion 66 has the greatest diameter. The inner portion 62 is formed with a central hole 68 formed with an internal thread. The distal end 66 is also formed with a threaded hole 70. The hole 70 extends perpendicular to and opens onto a planar face 72 of the terminal 56. In this embodiment, the face 72 lies in a plane perpendicular to a longitudinal axis 74 of the shaft 60.

The outer diameter of the distal portion 66 equal to the outer diameter of the posts 30, while the outer diameter of the intermediate portion 64 is marginally smaller than the inner diameter of the posts 30 so that the intermediate portion 64 can extend into the post 30. Indeed, a shoulder 65 formed between the distal portion 66 and the intermediate portion 64 forms a stop or seat for the posts 30 as shown most clearly in FIG. 5. The inner portion 62 is screwed onto a conducting fastener 76 to provide electrical connection to the sub-circuit 54 and mechanical fastening of the terminals 56 to the base 24. Electrically conducting fasteners 78 screw into the holes 70 in the distal portion 66 to mechanically and electrically couple the photovoltaic panels 22 to the connection system 10. A washer 80 may be placed between a head of the fastener 78 and the PV panels 22 to provide increased area of electrical connection between the PV panels 22 and the terminals 56.

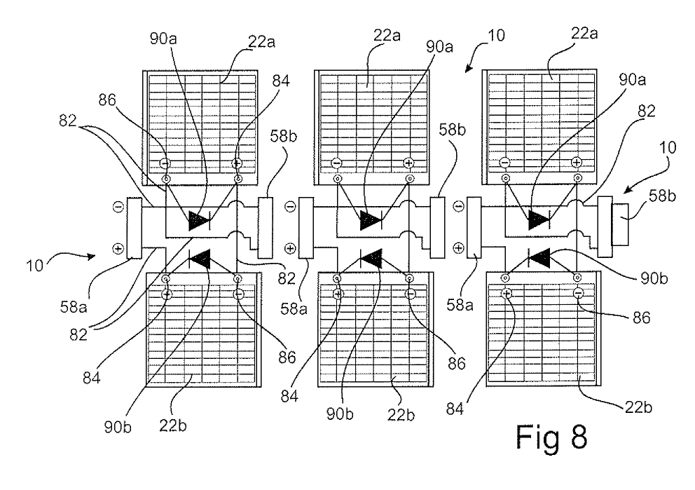

The sub-circuit 54 is shown schematically in FIG. 3 in situ inside the base 24: in FIG. 7 as a stand alone item connected with the connectors 58; and in FIG. 8 in circuit diagram form for each of three end to end coupled connection systems 10. The sub-circuit 54 comprises a plurality of conductors in the form of wires 82 which electrically connect with positive and negative terminals 84 and 86 of the PV panels 22. The electrical connection between the wires 82 and the outputs 84 and 86 is via the electrical terminals 56 as shown most clearly in FIG. 5. More particularly, the electrical wires 82 are coupled by lugs 88 to the electrical fasteners 76 which electrically connect to the electric terminals 56 which in turn electrically connect with the outputs 84 and 86 of the PV panels 22 via the electrical fasteners 78 and the washers 80.

The wires 82 are arranged to electrically connect the two PV panels 22a and 22b attached to a common connection system 10 in series. The sub-circuit 54 also comprises bypass diodes 90a and 90b (hereinafter referred to in general as “diodes 90”) which are connected between the terminals 56 coupled to a common PV panel 22. Electrically, this is equivalent to the bypass diodes 90 being connected between the positive and negative output terminals 84 and 86 of a particular PV panel 22. For example, in FIG. 8, diode 90a is shown as being coupled between the outputs 84 and 86 of PV panel 22a. The wires 82 are also connected to the connectors 58 to enable electrical connection between adjacent connection systems 10. In this embodiment, the sub-circuit 54 is arranged so that when the connectors 58 of adjacent connection systems 10 are coupled, the PV panels 22 of the respective coupled connection systems 10 are connected in series.

With reference to FIG. 2, the ridge plate 32 comprises two surfaces 92 and 94 which face the directions D1 and D2 respectively. The surfaces 92 and 94 are formed contiguously and form an edge 96. Each surface 92 and 94 is provided with holes 98 which register with the terminals 56 and the terminals 84 and 86 of a common PV panel 22. A plurality of support fingers 100 extend from the surfaces 92 and 94 in a plane of that surface. The fingers 100 lie beneath the PV panels 22 to provide cantilever support. When the PV panels 22 are connected to a connection system 10, the ridge plate 32 lies between the PV panels 22 and the base 24. This is shown most clearly in FIG. 5. When the connection system 10 is coupled with the photovoltaic panels 22 the resultant structure may be considered to be solar electric capping unit 102.

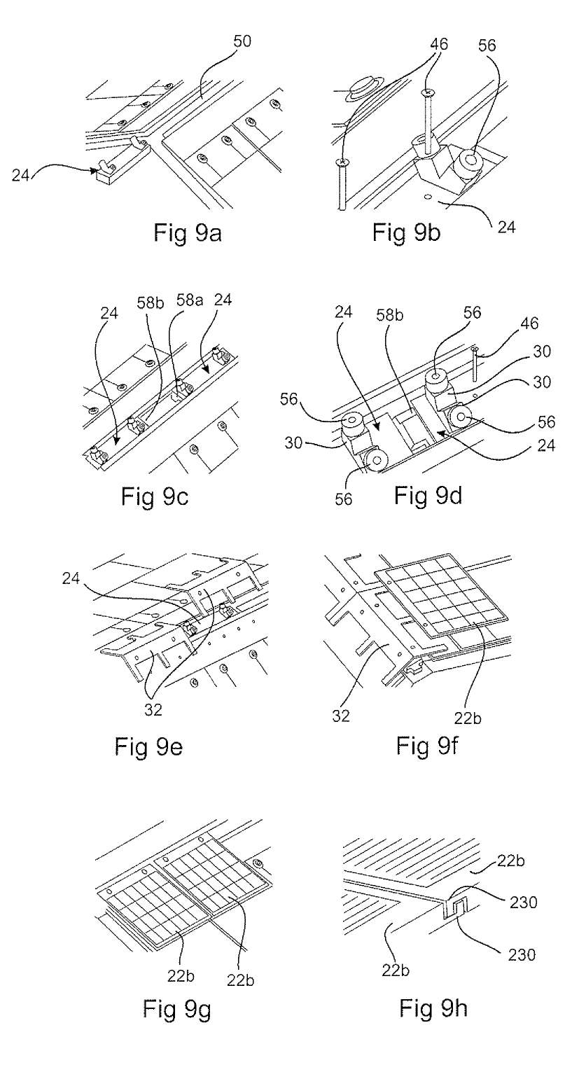

A method of installing a line of solar electric capping units 102 along ridge 12 of roof 14 is shown sequentially in FIGS. 9a-9h. In an initial step, base 24 of a first system 10 with pre-connected electric terminals 56 is placed on the underlying ridge beam 50. When the base 24 is located in the correct position, it is fixed to the beam 50 by use of screw fasteners such as screws or nails 46 which pass through the bosses 44 and through hole 48 in the cover plate 42. To install an adjacent second connection system 10, the base 24 of that system 10 is located on the ridge beam 50 and electrically connected with the base of the first connection system 10 by coupling their respective adjacent connectors 58 together as shown in FIG. 9c. This additional connection system 10 is again fastened in place by the use of screws or nails 46 in the same manner as described before. This process continues with a length of the ridge 12. Once all of the bases 24 have been electrically connected together and fixed to the underlying ridge beam 50, the ridge plate 32 of first connection system is located above its corresponding base 24 (FIG. 9e) and the PV panels 22 placed above the ridge plate 32 so that the terminals of that PV panel 22 register with the holes 98 in the ridge plate. The fasteners 78 with washers 80 are now passed through the terminals 84 and 86 of the PV panel 22 and threadingly engage the threaded hole 70 of a corresponding terminal 56 (FIGS. 9f and 9g). FIG. 9h shows the interlocking side edges of the PV panels 22b on two adjacent connection systems 10.

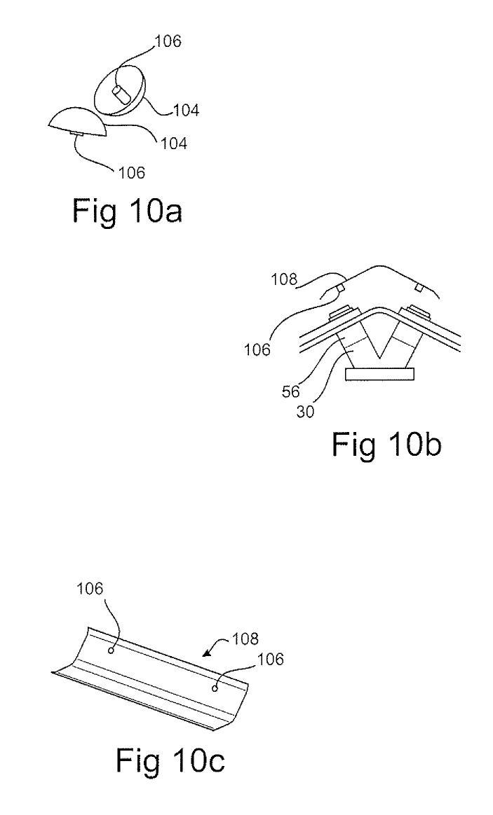

In order to prevent or at least minimise the risk of water contacting the fasteners 78 and indeed seeping through the terminals 84 and 86, protective snap on buttons 104 shown in FIG. 10a may be fitted over the fasteners 78. In an embodiment where the fasteners 78 are provided with Allen key type (i.e. hexagonal) holes 103 (see FIG. 5), the buttons 104 can be formed with centrally depending studs 106 that form an interference fit in the holes 103 of the fastener 78 to assist in retaining the buttons 104 on the fastener 78. If desired, a bead of sealant material may also be applied about the buttons 104. In addition or as an alternative to the buttons 104, an elongated capping 108 shown in FIGS. 10b and 10c may be applied over the fastener 78 of adjacent PV panels 22 coupled to a common connection system 10. The cover 108 is provided with a plurality of small studs 106 that are designed to fit into the holes in the fastener 78. In the event that the buttons 104 are also used, then holes (not shown) may be formed in the top of the buttons to receive the studs 106.

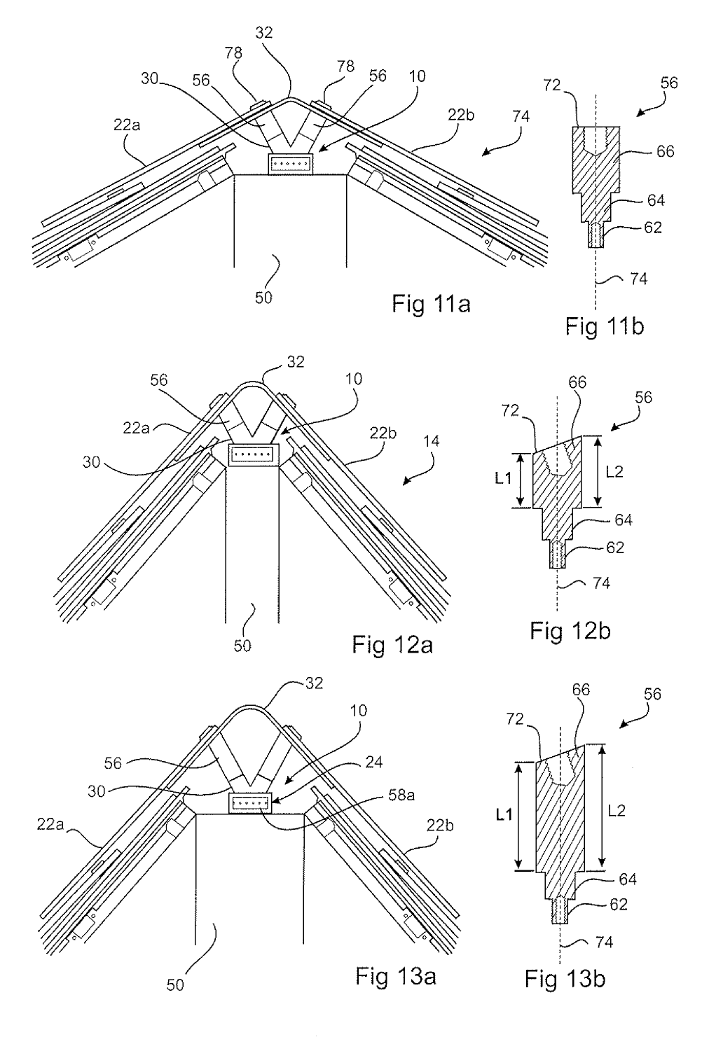

When the connection system 10 is used with roofs of different configuration, and in particular different pitch and/or different ridge beam width, a variety of different electric terminals 56 may be used to adapt the connection system 10 to the roof 14 at hand. In this regard, the terminals 56 are adapted by typically changing the length of their respective distal portion 66 and/or the angle of inclination of their face 72. This is shown most clearly by a reference to FIGS. 1b, 6 and 11a-13b. FIG. 1b shows a roof 14 having a 30° pitch and a 45 mm wide ridge beam 50. In this embodiment, the corresponding electric terminal 56 has a portion 66 of a length of 10 mm and a face 72 that lies in a plane perpendicular to the axis 74 of the terminal 56. FIGS. 11a and 11b depict a connection system 10 for a roof 14 again having a pitch of 30° but this time having a 100 mm wide ridge beam 50. In this embodiment, the terminal 56 differs from the terminal 56 shown in FIG. 6 by the length of its distal portions 66. In FIG. 11b the portion 66 has a length of 22.9 mm.

FIG. 12a shows a roof 14 having a pitch of 50° and a 45 mm wide roof beam 50. In this embodiment, the terminal 56 has a distal portion 66 with a minor length L1 of 18 mm and a major length L2 of 23.8 mm, and a face 72 inclined at an angle of 20° to the axis 74.

FIG. 13a shows a roof 14 of a pitch 50° and having a 100 mm wide ridge beam 50. In this embodiment, as shown in FIG. 13b, the terminal 56 has a distal portion 66 of a minimum length of 39.7 mm and the maximum length of 45.6 mm, and a face 72 disposed at an angle of 20° to the axis 74.

Now that embodiments of the present invention have been described in detail it will be apparent to those skilled in the relevant arts that numerous modifications and variations may be made without departing from the basic inventive concepts. For example, terminals 56 have been illustrated and described of four different configurations. However many different configurations may be provided in order to suit the application at hand particularly when applied to a roof 14. Further, while the connection system 10 has been described in relation to application on a roof 14, the connection system 10 may also be applied to other structures such as along the top of a wall or fence. In a further modification the PV tiles 22 coupled to a common connection system may be prefabricated onto a single carrier in which case the ridge plate 32 may not be required. For example the PV panels 22a and 22b may be moulded onto a curved carrier plate so as that the complete structure has a similar configuration to the PV panels 22 when coupled to the connection system 10. Further the carrier may be provided with an embedded metallic supporting plate or straps to replicate the function of the ridge plate 32. Indeed the PV cells which make up each plate can be fabricated into a single curved PV panel having either two sets of output connections 84 and 86 to replicate the outputs of the two PV panels 22a and 22b; or, have just a single pair of outputs 84 and 86 providing the electrical output for the entire curved panel. In the latter case the curved panel may still be mechanically couped at four points to the base 24, but only electrically coupled at two of these points. This structure may also simplify the sub-circuit 54 as only a single bypass diode will be required together with fewer wires 84. All such modifications and variations together with others that would obvious to a person of ordinary skill in the art are deemed to be within the scope of the present invention the nature of which is to be determined from the above description and the appended claims.

We claim:

1. A connection system for a solar electric power conversion system having a plurality of photovoltaic panels, the connection system comprising:
a base configured to support the photovoltaic panels in a manner where at least a first panel and a second panel face different respective first and second directions; and,
an electric circuit supported by the base for electrically coupling the photovoltaic panels together and enabling electrical connection of the connection system to a second like connection system.

2. The connection system according to claim 1 wherein the base is coupled to each of the panels at least two spaced apart locations.

3. The connection system according to claim 1 or 2 wherein the base supports each panel along a length of an edge thereof.

4. The connection system according to any one of claims 1-3 wherein the base comprises at least two posts for supporting the photovoltaic panels.

5. The connection system according to claim 4 wherein at least one of the posts extends in the first direction and at least one of the posts extends in the second direction.

6. The connection system according to claim 5 wherein at least two of the posts extend in the first direction and support the first photovoltaic panel, and at least two of the posts extend in the second direction and support the second photovoltaic panel.

7. The connection system according to claim 6 wherein the base comprises a first surface from which the posts extend.

8. The connection system according to claim 7 wherein the base comprises a cavity on a side of the first surface opposite the posts.

9. The connection system according to any one of claims 4-8 wherein the posts are integrally formed with the base.

10. The connection system according to claim 8 or 9 comprising a cover detachably coupled to the base to cover the cavity.

11. The connection system according to any one of claims 1-10 wherein the electrical connection system comprises a sub-circuit housed in the cavity.

12. The connection system according to claim 11 wherein the electric circuit comprises electric terminals coupled to the posts, the electric terminals providing electrical connection between the photovoltaic panels and the sub-circuit.

13. The connection system according to claim 12 wherein the sub-circuit is configured to electrically connect the photovoltaic panels in series.

14. The connection system according to any one of claims 11-13 wherein the sub-circuit comprises for each photovoltaic panel, a bypass diode electrically connected between the electric terminals coupled to corresponding photovoltaic panel.

15. The connection system according to any one of claims 1-14 wherein the electric circuit comprises first and second electrical connectors configured to enable electrical coupling of the connection system with a second like connection system.

16. The connection system according to any one of claims 12-15 wherein the electrical connectors are coupled with the sub-circuit in a manner whereby the photovoltaic panels coupled to the connection system are electrically coupled in series with photovoltaic panels coupled to a second like connection system.

17. The connection system according to any one of claims 12-16 wherein the electric terminals are demountably coupled to the posts to facilitate replacement of the electric terminals with terminals of different configuration.

18. The connection system according to any one of claims 12-17 where each electric terminal comprises a shaft of a first length, and a connection face at an end of the shaft, the connection face provided with a recess for receiving a fastener for fastening a photovoltaic panel to the electric terminal.

19. The connection system according to claim 18 wherein the electric terminals are provided with shafts having a selection of different lengths and connection faces lying in planes lying at a selection of different angles to a longitudinal axis of the shaft.

20. The connection system according to any one of claims 1-19 further comprising a ridge plate that comprises surfaces facing in both the first and second directions, the ridge plate connected to the base and underlying the photovoltaic panels.

21. A solar electric capping unit comprising:
first and second photovoltaic panels; and,
a connection system configured to support the panels in a manner wherein the first panel faces a first direction and a second panel faces a second direction different to the first direction, the connection system further arranged to electrically couple the photovoltaic panels together and to enable electrical connection with a second light solar capping unit.

22. The solar electric capping unit according to claim 21 wherein the connection system comprises the connection system according to any one of claims 1-20.
